(19) United States
(12) Patent Application Publication
(10) Pub. No.: US 2008/0128749 A1
(43) Pub. Date: Jun. 5, 2008

(54) Method and system for providing a drift coupled device

(76) Inventor: Darwin Gene Enicks, Colorodo Springs, CO (US)

Correspondence Address: DARWIN GENE ENICKS, 6845 SNOWBIRD DR., COLORADO SPRINGS, CO, 80918, US

(21) Appl. No.: 11/607,589

(22) Filed: Dec. 1, 2006

(51) Int. Cl. H01L 29/737; H01L 21/331

(52) U.S. Cl. 257/191; 438/312; 257/E29.188; 257/E21.371

(57) ABSTRACT

A method and system for providing a semiconductor device is described. The method and system include providing a compound region and providing a doped region. The compound region includes an alloy having an impurity. The impurity has a graded profile in the compound region. The doped region includes a dopant having a profile. The profile includes a retrograde region. In one aspect, the semiconductor device is a bipolar transistor. In this aspect, the method and system include providing an emitter region, a collector region, and a compound base region. The compound base region resides between the emitter region and the collector region. The compound base region has a collector side and includes an alloy and a dopant having a profile. The profile includes a retrograde region residing on the collector side of the compound base region.

### FIELD OF THE INVENTION

The present invention relates to semiconductor processing, and more particularly to a method and system for dopant profiles providing improved performance of heterostructure devices such as heterojunction bipolar transistor (HBT) devices.

### BACKGROUND OF THE INVENTION

SiGe devices such as SiGe metal oxide semiconductor field effect transistor (MOSFET), SiGe high electron mobility transistor (HEMT), SiGe high hole mobility transistor (HHMT), SiGe bipolar junction transistor (BJT), SiGe FinFET, and SiGe heterojunction bipolar transistor (HBT) devices may benefit from the use of the SiGe alloy. For example, a conventional SiGe HBT has significant advantages over a silicon BJT in gain, frequency response, noise parameters and retaining the ability to be readily integrated with CMOS at relatively low cost. Cutoff frequencies (fₜ) of conventional SiGe HBT devices have been reported to exceed 300 GHz, which is favorable as compared to GaAs devices. Moreover, GaAs devices are relatively high in cost and cannot achieve the level of integration of technologies such as BiCMOS. The silicon compatible conventional SiGe HBT provides a low cost, high speed, low power solution that is quickly replacing other compound semiconductor devices.

FIG. 1 depicts the film stack of a conventional heterojunction bipolar transistor (HBT) device 10 formed on a substrate 11. The conventional SiGe HBT device 10 includes a conventional collector region 12, a conventional base region 16, and a conventional emitter region 20. The conventional SiGe HBT device 10 may also include a conventional spacer (or seed) layer 14 and a conventional capping layer 18.

In a conventional SiGe HBT 10, the conventional spacer layer 14 is typically an elemental semiconductor, such as silicon. The conventional base region 16 is typically formed from a compound semiconductor, or alloy, such as SiGe. The compound layer of SiGe is typically composed of a silicon lattice having Ge impurities replacing some percentage of the Si atoms. The conventional capping layer 18 is typically an elemental semiconductor, such as silicon. The conventional emitter layer 18 is typically polysilicon. One of ordinary skill in the art will recognize that other materials of the poly-, mono-, and/or amorphous construction will also work well for the emitter layer, such as poly-SiGe or amorphous silicon, to name a few.

The conventional SiGe HBT 10 may be doped to be either npn or pnp, depending on the device application. For instance, with an npn SiGe HBT, the conventional collector region 12 may be doped with n-type dopants such as arsenic and/or phosphorus. The collector region 12 may be doped in-situ during epitaxial film growth or by ion implantation or diffusion sources after film growth. The conventional spacer 14, SiGe/SiGeC base layer 16, and the conventional cap layer 18 are typically formed together in the same process. The conventional spacer region 14 may be either undoped or doped with an n-type dopant. The conventional SiGe layer is typically grown using Silane (SiH₄) as the silicon source gas and germane (GeH₄) as the source of Ge impurities. The SiGe is typically epitaxially grown. The conventional capping layer 18 may be either doped or undoped.

Use of the conventional SiGe layer for the conventional base region 16 results in a base-emitter heterojunction that has several advantages. Because SiGe has a lower energy bandgap than silicon, the base-emitter heterojunction results in a bandgap offset between the conventional base 16 and the conventional emitter 20. This energy band offset may provide a higher collector current density (J_{c}). The base resistance, r_{B}, of the conventional SiGe HBT 10 may be reduced because of enhanced hole carrier mobility. In addition, SiGe is characterized by reduces diffusion of dopants, particularly B. Consequently, the conventional base 16 may have a significantly reduced base width. As a result, the transit time of charge carriers through the conventional base 16 may be reduced.

Although SiGe is beneficial in improving many aspects of performance, one of ordinary skill in the art will recognize that there are drawbacks, particularly for devices having a thin base region 16. In such a device the ability to maintain the desired relationship between the unity gain cutoff frequency and the maximum oscillation frequency may be compromised.

However, use of a graded impurity in a drift coupled device may improve the unity gain cutoff frequency and the maximum oscillation frequency. In particular, use of the graded profile increases the electric field, accelerating minority carriers across the base 16. In a drift coupled device, the concentration of the Ge impurity in the SiGe layer in which the base 16 is formed is graded. For example, FIG. 2 is a graph 50 depicting the dopant profiles for the conventional SiGe HBT 10 that is drift coupled. Thus, the conventional graph 50 includes profiles illustrating the positions of the As dopant 52 for the conventional emitter region 20, Ge dopant 56 for the SiGe layer of the conventional base region 16, and boron dopant 54 for the conventional base region 16. Note that the specific shapes and locations of the profiles 52, 54, and 56 for explanatory purposes and not necessarily meant to represent a particular real-world device. The B profile 54 is typically Gaussian shaped. In addition, as shown in FIG. 2, at the metallurgical junction 60 the bandgap offset is ΔEG(0) because x=0 is defined by the metallurgical junction. The bandgap offset at the grade of the Ge profile 56 is ΔEG(grade), where ΔEG(grade) is ΔEG(W_{b})−ΔEG(0), where W_{b} is the width of the base region as defined by the active boron profile. The built-in carrier drift E_{drift} for the device having profiles depicted in FIG. 2 is ΔEG(grade)/W_{b}. This built-in carrier drift may improve the acceleration of minority carriers across the conventional base 16.

Although drift coupled devices function, one of ordinary skill in the art will recognize that further improvements in performance of a SiGe device, particularly a drift coupled device, are desired.

Accordingly, what is needed is a method and system for improving the performance of a SiGe device, such as the SiGe HBT device 10. The present invention addresses such a need.

### BRIEF SUMMARY OF THE INVENTION

A method and system for providing a semiconductor device is described. The method and system include providing a compound region and providing a doped region. The compound region includes an alloy having an impurity. The impurity has a graded profile in the compound region. The doped region includes a dopant having a profile. The profile includes a retrograde region. In one aspect, the semiconductor device is a bipolar transistor. In this aspect, the method and system include providing an emitter region, a collector region, and a compound base region. The compound base region resides between the emitter region and the collector region. The compound base region has a collector side and includes an alloy and a dopant having a profile. The profile includes a retrograde region residing on the collector side of the compound base region.

According to the method and system disclosed herein a bipolar transistor having an improved electron drift may be fabricated.

### BRIEF DESCRIPTION OF SEVERAL VIEWS OF THE DRAWINGS

FIG. 1 is a diagram of a conventional heterojunction bipolar transistor device.

FIG. 2 depicts the dopant profile for a conventional heterojunction bipolar transistor device.

FIG. 3 is a diagram of one embodiment of a heterojunction bipolar transistor device in accordance with the method and system.

FIG. 4 depicts the dopant profiles for one embodiment of heterojunction bipolar transistor device.

FIG. 5 depicts the dopant profiles for another embodiment of heterojunction bipolar transistor device.

FIG. 6 depicts the dopant profiles for another embodiment of heterojunction bipolar transistor device.

FIG. 7 depicts the dopant profiles for another embodiment of heterojunction bipolar transistor device.

FIG. 8 depicts the dopant profiles for another embodiment of heterojunction bipolar transistor device.

FIG. 9 depicts the dopant profiles for another embodiment of heterojunction bipolar transistor device.

FIG. 10 depicts the dopant profile for the impurity in one embodiment of heterojunction bipolar transistor device.

FIG. 11 depicts the dopant profile for the impurity in another embodiment of heterojunction bipolar transistor device.

FIG. 12 depicts the dopant profile for the impurity in another embodiment of heterojunction bipolar transistor device.

FIG. 13 depicts the dopant profile for the impurity in another embodiment of heterojunction bipolar transistor device.

FIG. 14 depicts the dopant profile for the impurity in another embodiment of heterojunction bipolar transistor device.

FIG. 15 is a flow chart depicting one embodiment of a method for providing a semiconductor device.

FIG. 16 is a flow chart depicting one embodiment of a method for providing a SiGe HBT device.

FIG. 17 is a flow chart depicting another embodiment of a method for providing a SiGe HBT device.

### DETAILED DESCRIPTION OF THE INVENTION

The present invention relates to semiconductor devices. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

A method and system for providing a semiconductor device is described. The method and system include providing a compound region and providing a doped region. The compound region includes an alloy having an impurity. The impurity has a graded profile in the compound region. The doped region includes a dopant having a profile. The profile includes a retrograde region. In one aspect, the semiconductor device is a bipolar transistor. In this aspect, the method and system include providing an emitter region, a collector region, and a compound base region. The compound base region resides between the emitter region and the collector region. The compound base region has a collector side and includes an alloy and a dopant having a profile. The profile includes a retrograde region residing on the collector side of the compound base region.

The present invention will be described in terms of a particular HBT device. However, one of ordinary skill in the art will readily recognize that the method and system may be applicable to other device(s) having other, additional, and/or different components, dopants, and/or positions not inconsistent with the present invention. The present invention is also described in the context of particular methods. One of ordinary skill in the art will, however, recognize that the method could have other and/or additional steps. In addition, the steps of the methods may be performed in another order. Moreover, although the methods are described in the context of providing a single HBT device, one of ordinary skill in the art will readily recognize that multiple devices may be provided in parallel and/or series. The present invention is also described in the context of particular dopant profiles. However, one of ordinary skill in the art will readily recognize that the shapes, locations, and other features of the profiles may vary. The method is also described in the context of particular methods. However, one of ordinary skill in the art will recognize that the methods may omit or combine steps for ease of explanation. In addition, many industries allied with the semiconductor industry could make use of the method and system described herein. For example, the method and system might be used in conjunction with other devices including but not limited to MOSFETs, HEMT devices, HHMT devices, BJT devices, and FinFET devices. Thus, the terms used herein, including but not limited to the term semiconductor, may thus include the aforementioned and other industries. In addition, the method and system are described in the context of a SiGe compound device. However, one of ordinary skill in the art will recognize that the method and system may be used with other compound devices including but not limited to SiGeC devices.

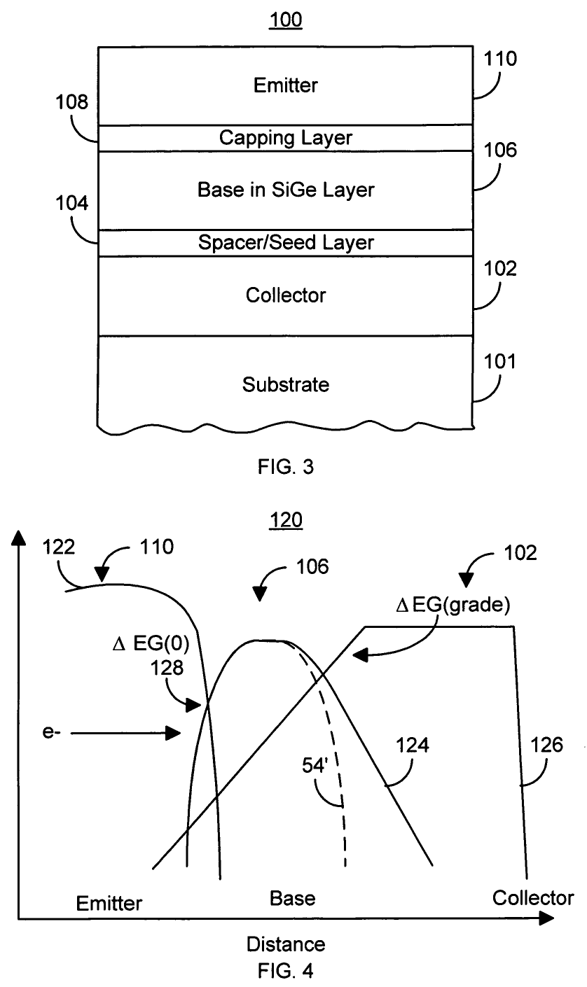

FIG. 3 is a diagram of one embodiment of a semiconductor device 100 in accordance with the method and system. The semiconductor device 100 shown is a SiGe HBT device 100 formed on a substrate 101. However in an alternate embodiment, another device may be formed. The SiGe HBT device 100 includes a collector region 102, a base region 106 formed in a SiGe layer (not depicted separately from the base 102), and a conventional emitter region 1110. The SiGe HBT device 100 might also include a conventional spacer (or seed) layer 104 and a conventional capping layer 108.

FIG. 4 is a graph 120 depicting the dopant profiles for one embodiment of a semiconductor device, such as the SiGe HBT device 100. For clarity, the graph 120 is described in the context of the SiGe HBT device 100, depicted in FIG. 3. However, the profiles 122, 124, and/or 126 might be used with different devices.

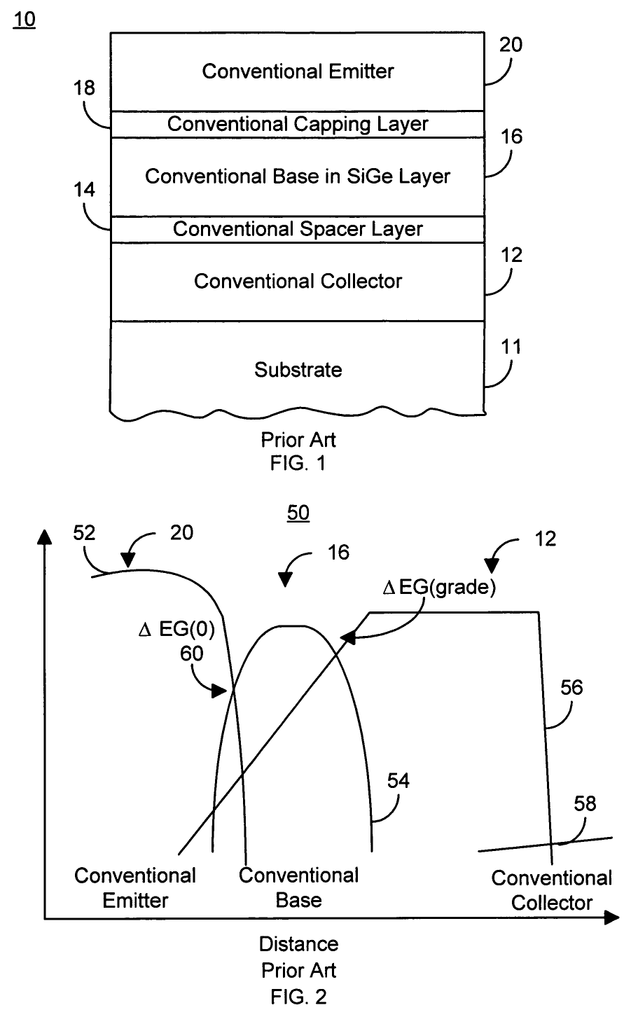

Referring to FIGS. 3-4, the graph 120 includes emitter dopant profile 122, base dopant profile 124, Ge profile 126, and alternate profile 54′. The emitter dopant profile 122 shown is for an n-type dopant, such as As or P. However, in another embodiment, another dopant may be used. The Ge profile 126 indicates the percentage of Ge impurity in the SiGe device 100, particularly in the SiGe layer in which the base 106 is formed. As indicated in FIG. 4, the Ge profile 126 is graded. Consequently, the SiGe device 100 is a drift coupled device. In a preferred embodiment, the emitter dopant profile 122 and Ge profile 126 may be the same as for a conventional device, such as those shown in FIGS. 1-2.

The base dopant profile 124 indicates the concentration of the dopant used for the base 106. In a preferred embodiment, the base dopant is B. Consequently, the profile 124 is referred to as a B profile 124. The alternate profile 54′ depicts the collector side of a profile for a base dopant that might have been used on a conventional device 10. Thus, the alternate profile 54′ is typically Gaussian in shape.

The B profile 124 is retrograde preferably on the collector 102 side of the SiGe HBT device 100. Stated differently, the B profile 124 is not symmetric in shape. Instead, in a preferred embodiment, additional B may be added on the retrograde (collector 102) side. Consequently, the magnitude of the slope of the B profile 124 on the collector 102 side is less than the magnitude of the slope of the B profile 124 on the emitter 110 side. Although the slope of the retrograde portion of the B profile 124 is depicted as substantially linear, another shape may be used.

Because the B profile 124 is retrograde, the electron drift for the SiGe HBT device 100 is improved. It is known that B acts as an acceptor ion in Si and/or SiGe because B is a Group III semiconductor. Such an acceptor ion takes on a net negative charge, for example donating a hole to the lattice of the SiGe or accepting an extra electron. Consequently, an additional drift for the electron is provided.

In operation, the base emitter junction 128 is forward biased. Consequently, electron injection from the emitter 110 is initiated. The initial electron injection may primarily be a diffusion mechanism due to the large and steep concentration of the n-type dopant shown in the emitter profile 122. After injection, an electron traversing the SiGe HBT device 100 travels toward the collector 102 and encounters a large positive drift field in the base region 106. This drift field is provided by the Ge in the graded Ge profile 126. In addition, as the electron traverses the base 106, the electron encounters a net-negative field induced by the ionized acceptors in the retrograde B profile 124. Because it is retrograde, the B profile 124 includes additional ionized acceptors in the region between the graded portion of the Ge profile 126 and the reverse-biased junction between the base 106 and collector 110. As a result, these additional ionized acceptors induce an additional drift component for the electrons. This additional drift field may be viewed as being coupled to the drift field induced by the Ge of the profile 126. Consequently, the additional drift field further enhances the velocity of the charge carriers through the SiGe HBT device 100.

Thus, use of the retrograde B profile 124, particularly in combination with the graded Ge profile 126 may enhance carrier velocity in a SiGe device 100. Optimization of the retrograde B profile thus provides an additional degree of freedom in designing a SiGe device such as the SiGe HBT device 100. The enhanced carrier velocity may also improve performance of the SiGe device 100 in a number of areas. For example, unity gain cutoff frequency, maximum oscillation frequency, current gain, and/or device efficiency may be improved.

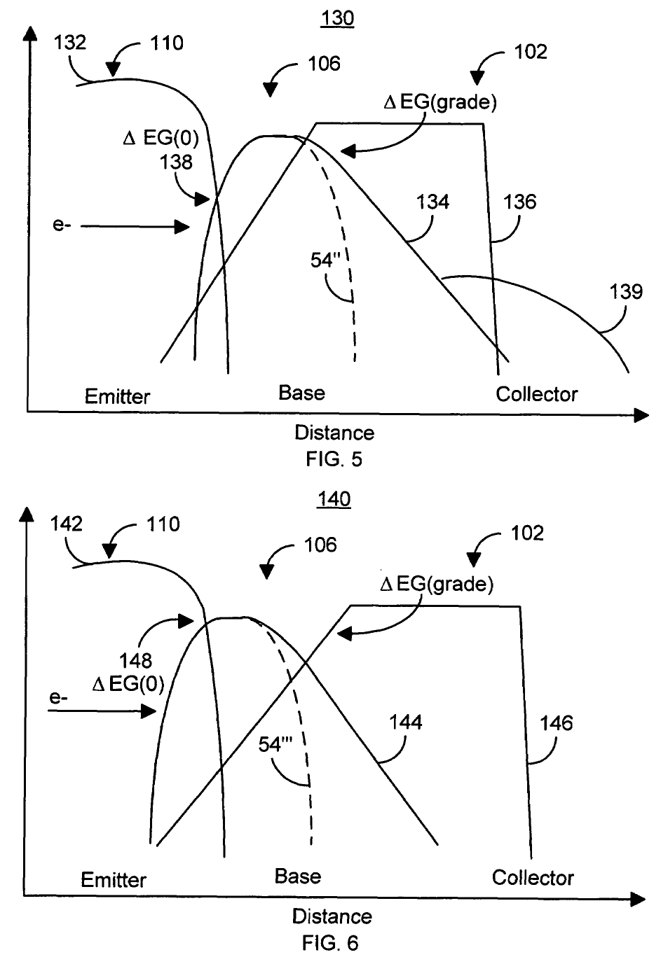

FIG. 5 depicts a graph 130 of the dopant profiles for another embodiment of heterojunction bipolar transistor device. For clarity, the graph 130 is described in the context of the SiGe HBT device 100, depicted in FIG. 3. However, the profiles 132, 134, and/or 136 might be used with different devices. In addition, the profiles 132, 134, 136, and 54″ and junction 138 are analogous to the profiles 122, 124, 126, and 54′ and junction 128, respectively, depicted in FIG. 4. Consequently, the profiles 132, 134, 136, and 54″ and junction 138 are labeled similarly.

Referring to FIGS. 3 and 5, the emitter dopant profile 132 is preferably an n-type dopant, such as As and/or P. The Ge profile 136 indicates that the concentration of Ge is graded in the base 106 region. In addition, the base dopant profile 134 is a retrograde profile. In a preferred embodiment, the base dopant is B. Consequently, the profile 134 is referred to as a B profile 134. The B profile 134 is retrograde preferably on the collector 102 side of the SiGe HBT device 100. Thus, the B profile 134 is not symmetric in shape. Instead, in a preferred embodiment, additional B may be added on the retrograde (collector 102) side. Although the slope of the retrograde portion of the B profile 134 is depicted as substantially linear, another shape may be used. The alternate profile 54″ depicts the collector side of a profile for a base dopant that might have been used on a conventional device 10. Thus, the alternate profile 54″ is typically Gaussian in shape.

In addition, the collector 102 includes a collector dopant having a retrograde profile 139. In the embodiment shown, the collector dopant is preferably an n-type dopant such as As or P. The collector dopant might be provided by retrograde doping the seed layer or by driving the dopant from the emitter through the base 106 and base-collector junction (not explicitly indicated in FIG. 5) and into the collector 102. The retrograde profile 139 provides an additional drift to charge carriers traversing the SiGe device 100.

Because the B profile 134 is retrograde, the electron drift for the SiGe HBT device 100 is improved. Thus, use of the retrograde B profile 134, particularly in combination with the graded Ge profile 136 may provide benefits analogous to those described above for the graph 120. In addition, use of the retrograde profile 139 for the collector dopant provides an additional drift. Thus, charge carrier velocity may be further enhanced.

FIG. 6 depicts a graph 140 of the dopant profiles for another embodiment of heterojunction bipolar transistor device. For clarity, the graph 140 is described in the context of the SiGe HBT device 100, depicted in FIG. 3. However, the profiles 142, 144, and/or 146 might be used with different devices. In addition, the profiles 142, 144, 146, and 54′″ and junction 148 are analogous to the profiles 122, 124, 126, and 54′ and junction 128, respectively, depicted in FIG. 4. Consequently, the profiles 142, 144, 146, and 54′″ and junction 148 are labeled similarly.

Referring to FIGS. 3 and 6, the emitter dopant profile 142 is preferably an n-type dopant, such as As and/or P. The Ge profile 146 indicates that the concentration of Ge is graded in the base 106 region. In a preferred embodiment, the base dopant is B. Consequently, the profile 144 is referred to as a B profile 144. The B profile 144 is a retrograde profile. This retrograde occurs in the same region in which the Ge profile 146 is graded. Thus, the B profile 144 is not symmetric in shape. Instead, in a preferred embodiment, additional B may be added. Although the slope of the retrograde portion of the B profile 144 is depicted as substantially linear, another shape may be used. The alternate profile 54′″ depicts the collector side of a profile for a base dopant that might have been used on a conventional device 10. Thus, the alternate profile 54′″ is typically Gaussian in shape.

Because the B profile 144 is retrograde, the electron drift for the SiGe HBT device 100 is improved. Thus, use of the retrograde B profile 144, particularly in combination with the graded Ge profile 146 may provide benefits analogous to those described above for the graph 120.

In addition, the B profile 144 is retrograde in the same region that the Ge profile 146 indicates that the concentration of the Ge impurity is graded. By tuning the combination of the retrograde of the B profile 144 and the grade of the Ge profile 146, the drift field may be optimized. In some of such embodiments, the drift field may be maximized. Consequently, charge carrier velocity through the SiGe device 100 may be further optimized.

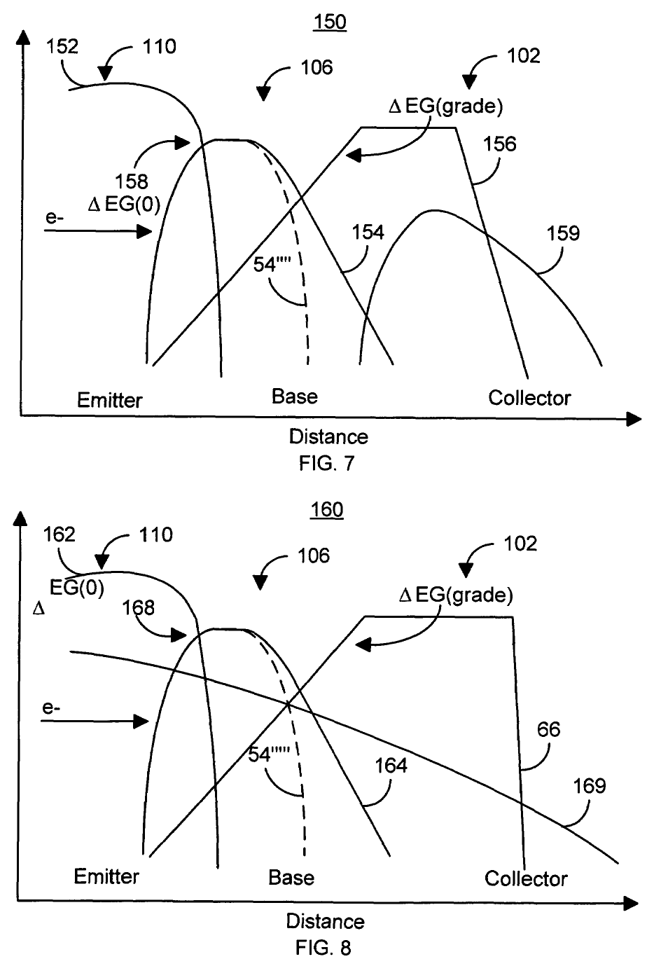

FIG. 7 depicts a graph 150 of the dopant profiles for another embodiment of heterojunction bipolar transistor device. For clarity, the graph 150 is described in the context of the SiGe HBT device 100, depicted in FIG. 3. However, the profiles 152, 154, and/or 156 might be used with different devices. In addition, the profiles 152, 154, 156, and 54″″ and junction 158 are analogous to the profiles 122, 124, 126, and 54′ and junction 128, respectively, depicted in FIG. 4. Consequently, the profiles 152, 154, 156, and 54″″ and junction 158 are labeled similarly.

Referring to FIGS. 3 and 7, the emitter dopant profile 152 is preferably an n-type dopant, such as As and/or P. The Ge profile 156 indicates that the concentration of Ge is graded in the base 106 region. In a preferred embodiment, the base dopant is B. Consequently, the profile 154 is referred to as a B profile 154. The B profile 154 is a retrograde profile. This retrograde occurs in the same region in which the Ge profile 156 is graded. Thus, the B profile 154 is not symmetric in shape. Instead, in a preferred embodiment, additional B may be added. Although the slope of the retrograde portion of the B profile 154 is depicted as substantially linear, another shape may be used. The alternate profile 54″″ depicts the collector side of a profile for a base dopant that might have been used on a conventional device 10. Thus, the alternate profile 54″″ is typically Gaussian in shape.

Because the B profile 154 is retrograde, the electron drift for the SiGe HBT device 100 is improved. Thus, use of the retrograde B profile 154, particularly in combination with the graded Ge profile 156 may provide benefits analogous to those described above for the graph 120. In addition, the B profile 154 is retrograde in the same region that the Ge profile 156 indicates that the concentration of the Ge impurity is graded. By tuning the combination of the retrograde of the B profile 154 and the grade of the Ge profile 156, the drift field may be optimized. In some of such embodiments, the drift field may be maximized. Consequently, charge carrier velocity through the SiGe device 100 may be further optimized.

In addition, the Ge profile 156 is also retrograde on the collector 102 side. Retrograding the Ge profile 156 on the collector 102 side results in an increase in the base-collector breakdown voltage and collector-emitter breakdown voltage. However, without more, retrograding the Ge profile 156 would result in a drift field that works against electron transport. Retrograding the B profile 154 may aid in offsetting losses due to the retrograding of the Ge profile 156. In addition, the collector 102 includes a collector dopant having a retrograde profile 159. In the embodiment shown, the collector dopant is preferably an n-type dopant such as As or P. The collector dopant might be provided by retrograde doping the seed layer or by driving the dopant from the emitter through the base 106 and base-collector junction (not explicitly indicated in FIG. 7) and into the collector 102. The retrograde profile 159 provides an additional drift to charge carriers traversing the SiGe device 100. Thus, charge carrier velocity may be further enhanced.

FIG. 8 depicts a graph 160 of the dopant profiles for another embodiment of heterojunction bipolar transistor device. For clarity, the graph 160 is described in the context of the SiGe HBT device 100, depicted in FIG. 3. However, the profiles 162, 164, and/or 166 might be used with different devices. In addition, the profiles 162, 164, 166, and 54′″″ and junction 168 are analogous to the profiles 122, 124, 126, and 54 and junction 128, respectively, depicted in FIG. 4. Consequently, the profiles 162, 164, 166, and 54′″″ and junction 168 are labeled similarly.

Referring to FIGS. 3 and 8, the emitter dopant profile 162 is preferably an n-type dopant, such as As and/or P. The Ge profile 166 indicates that the concentration of Ge is graded in the base 106 region. In a preferred embodiment, the base dopant is B. Consequently, the profile 164 is referred to as a B profile 164. The B profile 164 is a retrograde profile. This retrograde occurs in the same region in which the Ge profile 166 is graded. Thus, the B profile 164 is not symmetric in shape. Instead, in a preferred embodiment, additional B may be added. Although the slope of the retrograde portion of the B profile 164 is depicted as substantially linear, another shape may be used. The alternate profile 54′″″ depicts the collector side of a profile for a base dopant that might have been used on a conventional device 10. Thus, the alternate profile 54′″″ is typically Gaussian in shape.

Because the B profile 164 is retrograde, the electron drift for the SiGe HBT device 100 is improved. Thus, use of the retrograde B profile 164, particularly in combination with the graded Ge profile 166 may provide benefits analogous to those described above for the graph 120. In addition, the B profile 164 is retrograde in the same region that the Ge profile 166 indicates that the concentration of the Ge impurity is graded. By tuning the combination of the retrograde of the B profile 164 and the grade of the Ge profile 166, the drift field may be optimized. In some of such embodiments, the drift field may be maximized. Consequently, charge carrier velocity through the SiGe device 100 may be further optimized.

Moreover, a dopant is provided throughout the device 100, as shown by the dopant profile 169. The dopant provided is preferably an n-type dopant. In one embodiment, the dopant profile 169 is achieved by implanting the n-type dopant in the cap layer 108 and/or emitter layers 110. The dopant is then allowed to diffuse through the base 106 and to the collector 102. As can be seen in FIG. 8, the dopant profile 169 may be considered to be a retrograde profile. Use of the retrograde profile 169 for the collector dopant provides an additional drift. Thus, charge carrier velocity may be further enhanced.

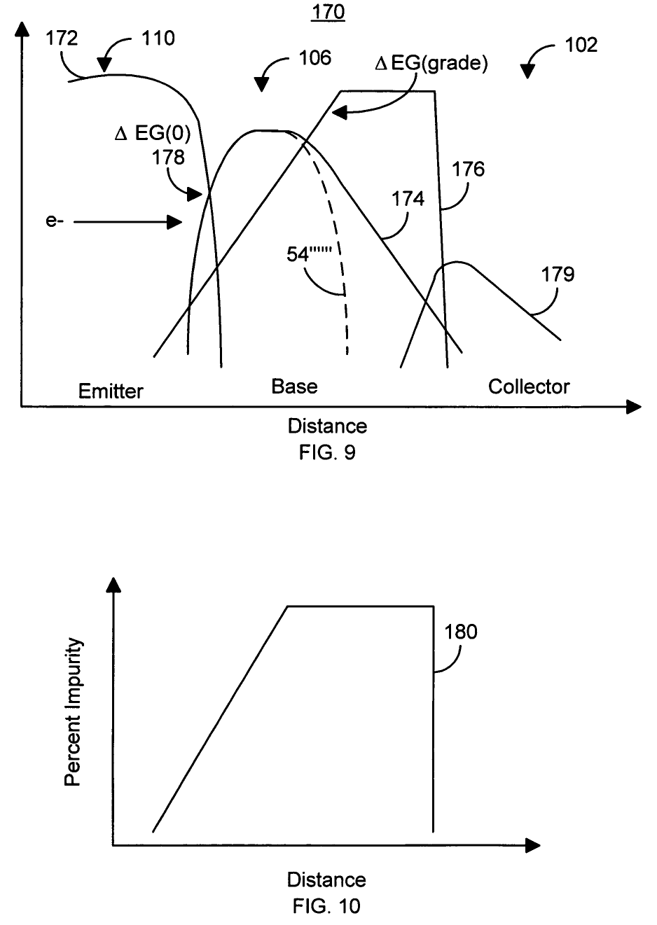

FIG. 9 depicts a grapy 170 of the dopant profiles for another embodiment of heterojunction bipolar transistor device. For clarity, the graph 170 is described in the context of the SiGe HBT device 100, depicted in FIG. 3. However, the profiles 172, 174, and/or 176 might be used with different devices. In addition, the profiles 172, 174, 176, and 54″″″ and junction 178 are analogous to the profiles 122, 124, 126, and 54 and junction 128, respectively, depicted in FIG. 4. Consequently, the profiles 172, 174, 176, and 54″″″ and junction 178 are labeled similarly. In addition, the profiles 172, 174, 176, 179, and junction 178 are analogous to the profiles 162, 164, 166, 169 and junction 168 depicted in FIG. 8.

Referring to FIGS. 3 and 9, the emitter dopant profile 172 is preferably an n-type dopant, such as As and/or P. The Ge profile 176 indicates that the concentration of Ge is graded in the base 106 region. In a preferred embodiment, the base dopant is B. Consequently, the profile 174 is referred to as a B profile 174. The B profile 174 is a retrograde profile. This retrograde occurs in the same region in which the Ge profile 176 is graded. Thus, the B profile 174 is not symmetric in shape. Instead, in a preferred embodiment, additional B may be added. Although the slope of the retrograde portion of the B profile 174 is depicted as substantially linear, another shape may be used. The alternate profile 54″″″ depicts the collector side of a profile for a base dopant that might have been used on a conventional device 10. Thus, the alternate profile 54″″″ is typically Gaussian in shape.

Because the B profile 174 is retrograde, the electron drift for the SiGe HBT device 100 is improved. Thus, use of the retrograde B profile 174, particularly in combination with the graded Ge profile 176 may provide benefits analogous to those described above for the graph 120. In addition, the B profile 174 is retrograde in the same region that the Ge profile 176 indicates that the concentration of the Ge impurity is graded. By tuning the combination of the retrograde of the B profile 174 and the grade of the Ge profile 176, the drift field may be optimized. In some of such embodiments, the drift field may be maximized. Consequently, charge carrier velocity through the SiGe device 100 may be further optimized.

Moreover, a dopant is provided throughout the device 100, as shown by the dopant profile 179. The dopant is analogous the dopant resulting in the profile 169 depicted in FIG. 8. Referring back to FIG. 9, the profile 179 is also preferably an n-type dopant. In one embodiment, the dopant profile 179 is achieved by performing in-situ doping of the seed layer (not explicitly shown). As can be seen in FIG. 8, the dopant profile 179 may be considered to be a retrograde profile. Use of the retrograde profile 179 for the collector dopant provides an additional drift. Thus, charge carrier velocity may be further enhanced.

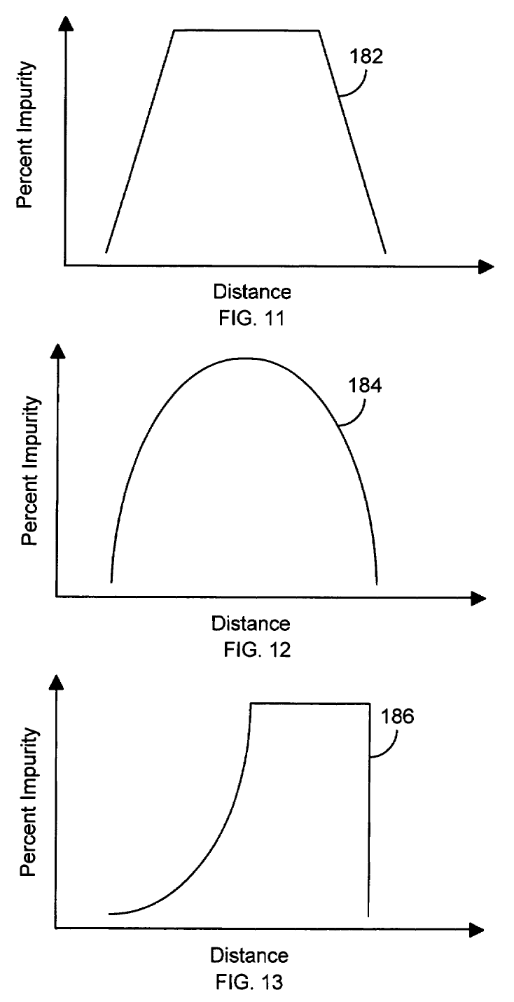

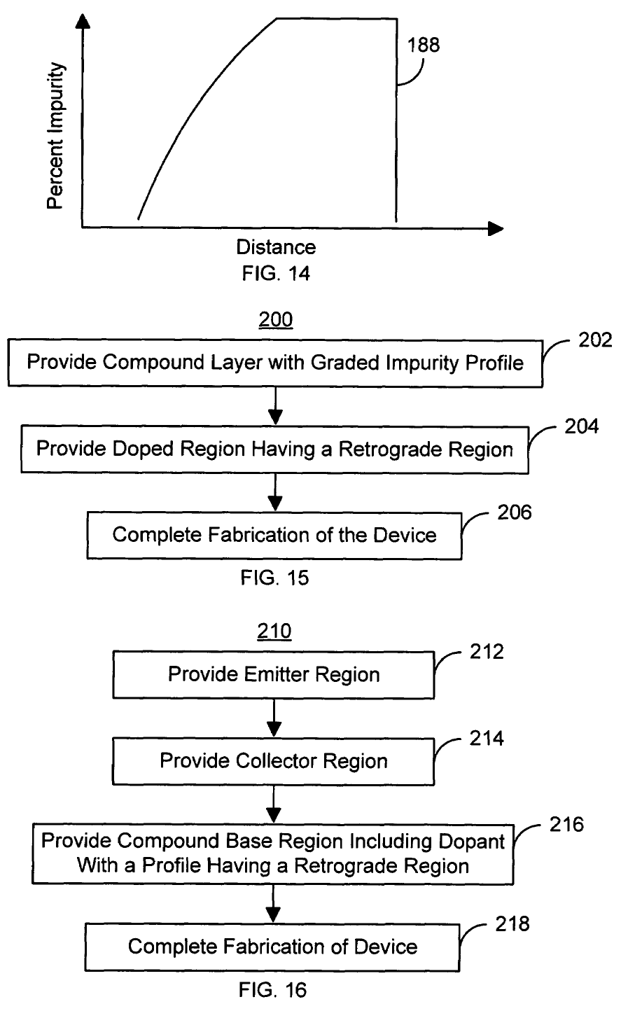

Although the graphs 120, 130, 140, 150, 160, and 170 have been described in terms of Ge profiles 126, 136, 146, 156, 166, and 176, respectively, one of ordinary skill in the art will recognize that the SiGe layer for the base 106 may have other Ge profiles. Examples of some alternate Ge profiles are depicted in FIGS. 10-14. FIG. 10 depicts the Ge profile 180 for the impurity in one embodiment of heterojunction bipolar transistor device 100. The profile 180 is known as a box plus graded profile. The grade on the profile 180 provides a built-in drift field to enhance electron transport across the base. FIG. 11 depicts another Ge profile 182 for the impurity in another embodiment of heterojunction bipolar transistor device 100. The profile 182 is known as a trapezoid profile. The grade on the base emitter side of the profile 182 provides a built-in drift field to enhance electron transport. FIG. 12 depicts another Ge profile 184 for the impurity in another embodiment of heterojunction bipolar transistor device. The Ge profile 184 has a curvature. The grade on the base emitter side of the profile provides a built-in drift field to enhance electron transport. FIG. 13 depicts another Ge profile 186 for the impurity in another embodiment of heterojunction bipolar transistor device. The profile 186 also has a curvature and may be considered a box profile with a concave graded section. The grade of the profile 186 provides a built-in drift field to enhance electron transport. FIG. 14 depicts another Ge profile 188 for the impurity in another embodiment of heterojunction bipolar transistor device. The profile 188 also has a curvature and may be considered a box profile with a convex graded section. The grade of the profile 188 provides a built-in drift field to enhance electron transport.

FIG. 15 is a flow chart depicting one embodiment of a method 200 for providing a semiconductor device. The method 200 is described in the context of the semiconductor device 100 and graph 120. However, one of ordinary skill in the art will recognize that the method 200 may be used with other semiconductor devices and other profiles including but not limited to those shown in FIGS. 5-14. Referring to FIGS. 3, 4, and 17, a compound region including an alloy having an impurity, is provided, via step 202. In a preferred embodiment, the compound region includes SiGe and the impurity is Ge. Also in a preferred embodiment, step 202 includes grading the profile 126 of the impurity in the compound region. A doped region is provided, via step 204. The doped region preferably resides at least in part within the compound region. The dopant is preferably B. The doped region has a profile 124. Thus, step 204 includes ensuring that the B profile 124 has a retrograde region. The retrograde region may be provided in step 204 by ramping the source of the dopant being implanted. Fabrication of the device 100 may then be completed, via step 206.

Using the method 200, a compound device, such as the device 100, having graded and retrograde profiles such as those depicted in FIGS. 4-14 may be provided. Consequently, the benefits described above with respect to FIGS. 4-14 may be achieved.

FIG. 16 is a flow chart depicting one embodiment of a method 210 for providing a SiGe HBT device. The method 210 is described in the context of the semiconductor device 100 and graph 120. However, one of ordinary skill in the art will recognize that the method 210 may be used with other semiconductor devices and other profiles including but not limited to those shown in FIGS. 5-14. Referring to FIGS. 3, 4, and 17, an emitter region 110 is provided, via step 212. Step 212 may include doping the emitter region. Thus, a dopant having a profile such as the profile 122 may be provided. The collector region 102 is provided, via step 214. Note that step 214 is typically performed before step 212. Step 214 may include doping the collector region. For example, profiles such as the profiles 139, 159, 169, or 179 might be provided. A compound base region 106 is provided between the emitter region 110 and the collector region 102, via step 216. Step 216 preferably includes forming a compound region, or alloy, that is preferably SiGe. In addition, a dopant that is preferably B is provided in the compound base region 106 in step 216. Step 216 includes ensuring that the profile 124 of the dopant includes a retrograde region that resides on the collector side of the compound base region 106.

Using the method 200, a compound device, such as the device 100, having graded and retrograde profiles such as those depicted in FIGS. 4-14 may be provided. Consequently, the benefits described above with respect to FIGS. 4-14 may be achieved.

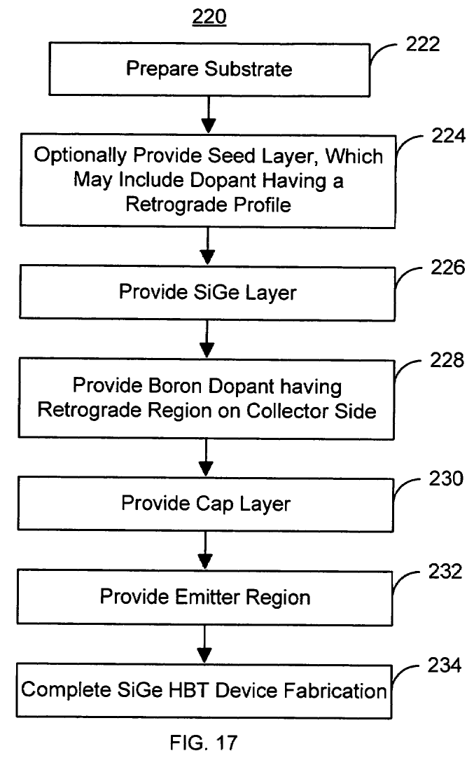

FIG. 17 is a flow chart depicting another embodiment of a method 220 for providing a SiGe HBT device. The method 220 is described in the context of the semiconductor device 100 and graph 120. However, one of ordinary skill in the art will recognize that the method 220 may be used with other semiconductor devices and other profiles including but not limited to those shown in FIGS. 5-14.

Referring to FIGS. 3, 4, and 17, the substrate 101 of the semiconductor device 100 is prepared for growth of the semiconductor device 100, via step 202. Step 202 may include steps such as a surface preclean, for example using hydrofluoric acid diluted with de-ionized water, and a prebake. The prebake may be carried out in a hydrogen or inert ambient. In addition, a hydrogen containing dopant, such as AsH₃, may be used to provide a sharp n-type dopant profile at the base-collector junction.

A seed layer 102 may be grown, via step 224. Preferably, a silicon seed layer is grown from thermal and/or chemical decomposition of a precursor such as SiH₄ or Si₂H₆. However, in another embodiment, other seed layers 102 may be provided. In one embodiment, the thickness of the seed layer 102 is at least ten nanometers, but not more than one hundred nanometers. However, in alternate embodiments, other thicknesses may be used. Also in step 224, a retrograde dopant for the collector region may be provided. For example, the dopant for the profiles 139, 159, and 179 depicted in FIGS. 5, 7, and 9 may be provided in step 224. In addition to the retrograde dopant, an n-type dopant such as As or P may be used. In such embodiments, the dopant concentration is preferably 5×10¹⁷ atoms/cm³ through 5×10¹⁸ atoms/cm³. However, other embodiments may include other concentrations.

A compound/alloy layer include SiGe is provided, via step 226. The resulting layer preferably has a graded profile, such as the Ge profile 126. However, various profiles for the Ge impurity may be formed. Examples of such profiles may be found in FIGS. 5-14. Referring back to FIGS. 3, 4, and 17, step 226 may include forming SiGe multilayers. The thickness of the SiGe layer (or multilayer) formed in step 224 is preferably at least twenty-five nanometers and not more than fifty nanometers. However, in other embodiments, different thicknesses may be formed. One of ordinary skill in the art will recognize that SiGe is strained and, for thicknesses greater than a critical thickness may be in a metastable or unstable state. In metastable or unstable states, the SiGe layer may be subject to relaxation during downstream processing. Consequently, thickness the SiGe layer may be desired to be less than the critical thickness. In addition, carbon or other dopants may also be provided in step 226. SiH4 is preferably the source of Si, while GeH4 is the preferred

The boron dopant having a profile 124 with a retrograde region on the collector side is provided, via step 228. Consequently, through step 226 and 228 the compound base 106 may be formed. In a preferred embodiment, step 228 includes utilizing a flow of B₂H₆. In a preferred embodiment, the retrograde region is provided by ramping the flow of B₂H₆.

A cap layer 108 may be provided, via step 230. Note that providing the cap layer 108 may be considered part of the process of forming the emitter region 110. In a preferred embodiment, the cap layer 108 is at least fifteen nanometers and not more than fifty-five nanometers thick. However, in alternate embodiments, other thicknesses may be used. The thickness of the cap layer 108 may be used to tune placement of the metallurgical/heterojunction at base-emitter side of the SiGe HBT device 100. The cap layer 108 is preferably undoped. However, in alternate embodiments, the cap layer 108 may be doped, for example with As or P.

The emitter region 110 is provided, via step 232. Step 232 may include doping the emitter region 110. For example, dopants such as As or P may be used. Fabrication of the SiGe HBT device 100 may be completed, via step 234.

Using the method 220, a compound device, such as the device 100, having graded and retrograde profiles such as those depicted in FIGS. 4-14 may be provided. Consequently, the benefits described above with respect to FIGS. 4-14 may be achieved.

A method and system for providing a retrograde dopant in a compound semiconductor devices, such as a drift coupled SiGe HBT devices, has been disclosed. The present invention has been described in accordance with the embodiments shown, and one of ordinary skill in the art will readily recognize that there could be variations to the embodiments, and any variations would be within the spirit and scope of the present invention. Accordingly, many modifications may be made by one of ordinary skill in the art without departing from the spirit and scope of the appended claims.

What is claimed is:

1. A semiconductor device comprising:
a compound region including an alloy having an impurity, the impurity having a graded profile in the compound region; and
a doped region having a dopant having a profile, the profile including a retrograde region.

2. A bipolar transistor comprising:
an emitter region;
a collector region; and
a compound base region between the emitter region and the collector region, the compound base region having a collector side and including an alloy and a dopant having a profile, the profile including a retrograde region, the retrograde region residing on the collector side of the compound base region.

3. The bipolar transistor of claim 2 wherein the alloy includes an impurity having a graded profile in the compound base region.

4. The bipolar transistor of claim 3 wherein the impurity is Ge.

5. The bipolar transistor of claim 2 wherein the dopant is B.

6. The bipolar transistor of claim 5 wherein the profile of the dopant further includes a Gaussian region in the compound base region.

7. The bipolar transistor of claim 2 further comprising:
an additional dopant residing in at least a portion of the collector region, the additional dopant having a retrograde profile in the collector region.

8. The bipolar transistor of claim 7 wherein the additional dopant includes As.

9. A bipolar transistor comprising:
an emitter region;
a collector region; and
a compound base region between the emitter region and the collector region, the compound base region having a collector side and including SiGe and a B dopant having a profile, the profile including a retrograde region, the retrograde region residing on the collector side of the compound base region, Ge of the SiGe having a graded profile in the compound base region;
wherein an As dopant resides in at least a portion of the collector region, the As dopant having a retrograde profile in the collector region.

10. A method for providing a semiconductor device comprising:
providing a compound region including an alloy having an impurity, the impurity having a graded profile in the compound region; and
providing a doped region having a dopant having a profile, the profile including a retrograde region.

11. A method for providing a semiconductor device comprising:
providing an emitter region;
providing a collector region; and
providing a compound base region between the emitter region and the collector region, the compound base region having a collector side including an alloy and a dopant having a profile, the profile including a retrograde region, the retrograde region residing on the collector side of the compound base region.

12. The method of claim 11 wherein the compound base region providing further includes:
growing an alloy including an impurity having a graded profile in the compound base region.

13. The method of claim 12 wherein the alloy growing further includes:
growing a SiGe layer, the impurity having the graded profile being Ge.

14. The method of claim 13 wherein the compound base region providing further includes:
doping the alloy layer with the dopant, the dopant being B.

15. The method of claim 14 wherein the profile of the dopant further includes a Gaussian region in the compound base region.

16. The method of claim 11 further comprising:
providing an additional dopant residing in at least a portion of the collector region, the additional dopant having a retrograde profile in the collector region.

17. The method of claim 16 wherein the additional dopant providing further includes:
providing a seed layer for the compound base region, the additional dopant being provided in the seed layer alloy includes a first constituent having a graded profile in the compound base region.

18. The method of claim 17 wherein the additional dopant includes As.

19. A method for providing a semiconductor device including a collector region, an emitter region, and a compound base region between the collector region and the emitter region, the compound base region having a collector side, the method comprising:
providing a seed layer,
doping the seed layer with an n-type dopant, the n-type dopant having a retrograde profile in the collector region;
growing a SiGe layer on the seed layer, the Ge having a graded profile in the compound base region;
doping the compound base region with a B dopant having a profile, the profile including a retrograde region residing on the collector side of the compound base region.

20. The method of claim 19 wherein the doping further includes:
flowing a B-containing gas over the semiconductor device.

21. The method of claim 20 the doping further includes:
ramping a flow of the B-containing base down during the doping.
